(19) United States
(12) Patent Application Publication
(10) Pub. No.: US 2010/0021844 A1
(43) Pub. Date: Jan. 28, 2010

(54) NEGATIVE-WORKING IMAGEABLE ELEMENTS AND METHOD OF USE

(76) Inventors: Jianfei Yu, Fort Collins, CO (US); Kevin B. Ray, Fort Collins, CO (US); Shashikant Saraiya, Fort Collins, CO (US)

Correspondence Address: J. Lanny Tucker;Patent Legal Staff, Eastman Kodak Company, 343 State Street, Rochester, NY, 14650-2201, US

(21) Appl. No.: 12/177,208

(22) Filed: Jul. 22, 2008

(51) Int. Cl. G03F 7/20; G03C 1/043

(52) U.S. Cl. 430/273.1; 430/270.1; 430/283.1; 430/280.1; 430/325; 430/302

(57) ABSTRACT

Negative-working imageable elements can be imaged and processed with water to provide lithographic printing plates. These imageable elements have imageable layers that contain a particulate polymeric binder having polyetheramine side chains. Rapid processing speeds are also possible using water and optional mechanical rubbing means for processing the imaged element.

### FIELD OF THE INVENTION

This invention provides negative-working imageable elements that can be used to prepare lithographic printing plates. The imageable elements contain particulate primary polymeric binders that comprise pendant polyetheramine groups. This invention also relates to methods of imaging and processing such imageable elements.

### BACKGROUND OF THE INVENTION

In conventional or “wet” lithographic printing, ink receptive regions, known as image areas, are generated on a hydrophilic surface. When the surface is moistened with water and ink is applied, the hydrophilic regions retain the water and repel the ink, and the ink receptive regions accept the ink and repel the water. The ink is transferred to the surface of a material upon which the image is to be reproduced. For example, the ink can be first transferred to an intermediate blanket that in turn is used to transfer the ink to the surface of the material upon which the image is to be reproduced.

Imageable elements useful to prepare lithographic printing plates typically comprise at least one imageable layer applied over the hydrophilic surface of a substrate. The imageable layer(s) include one or more radiation-sensitive components that can be dispersed in a suitable binder. Alternatively, the radiation-sensitive component can also be the binder material. Following imaging, either the imaged regions or the non-imaged regions of the imageable layer are removed by a suitable developer, revealing the underlying hydrophilic surface of the substrate. If the imaged (exposed) regions are removed, the element is considered as positive-working. Conversely, if the non-imaged (non-exposed) regions are removed, the element is considered as negative-working. In each instance, the regions of the imageable layer (that is, the image areas) that remain are ink-receptive, and the regions of the hydrophilic surface revealed by the developing process accept water or a fountain solution and repel ink.

Direct digital imaging has become increasingly important in the printing industry. Imageable elements for the preparation of lithographic printing plates have been developed for use with infrared lasers.

Negative-working imageable elements useful for preparing lithographic printing plates are well known in commerce as well as hundreds of publications. For example, U.S. patent application Publication 2005/0123853 (Munnelly et al.) describes negative-working imageable elements that can be processed off-press using an aqueous solution or on-press using a lithographic printing ink and fountain solution. These elements contain polymeric binders having pendant groups containing alkylene oxide segments.

### Problem to be Solved

While the industry and various publications have provided negative-working imageable elements with various properties, they are generally processed after imaging using high pH aqueous developers or organic-solvent containing developers. It would be desirable to have negative-working imageable elements that can be processed using a lower pH solution such as water that is more environmentally acceptable.

### SUMMARY OF THE INVENTION

This invention provides a negative-working imageable element comprising a substrate and having thereon an imageable layer comprising:

a free-radically polymerizable component,

an initiator composition that is capable of generating free radicals sufficient to initiate polymerization of the free-radically polymerizable component upon exposure to imaging radiation in the presence of a radiation absorbing compound,

a radiation absorbing compound, and

a polymeric binder that is present as discrete particles and comprises polyetheramine side chains connected to a backbone.

This invention also provides a method of making an image comprising:
A) imagewise exposing the negative-working imageable element of this invention to imaging radiation to provide both exposed and non-exposed regions in the imageable layer, and
B) applying water to the imaged element to remove predominantly only the non-exposed regions.

Thus, the method of this invention can be used to prepare lithographic printing plates, particularly those having aluminum-containing substrates.

Surprisingly, the negative-working imageable elements of this invention can be imaged and then processed or developed using simply water. This is possible because of the particular polymeric binder that is present in the imageable layer, which polymeric binder has pendant polyetheramine side chains and is present in particulate form.

### BRIEF DESCRIPTION OF THE DRAWINGS

FIG. 1 is a black-and-white scanning electron microscope image at 20,000 magnitude of the imageable layer obtained for Invention Example 1 described below, showing the discrete polymeric binder particles in that imageable layer.

FIG. 2 is a black-and-white scanning electron microscope image at 20,000 magnitude of the imageable layer obtained for Comparative Example 1 described below, showing the lack of discrete polymeric binder particles in that imageable layer.

### DETAILED DESCRIPTION OF THE INVENTION

### Definitions

Unless the context indicates otherwise, when used herein, the terms “imageable element”, “lithographic printing plate precursor” and “negative-working imageable element” are meant to be references to embodiments of the present invention.

In addition, unless the context indicates otherwise, the various components described herein such as “primary polymeric binder”, “secondary polymeric binder”, “free-radically polymerizable component”, “initiator”, “radiation absorbing compound”, “IR dye”, and similar terms also refer to mixtures of such components. Thus, the use of the article “a” or “an” is not necessarily meant to refer to only a single component.

By the term “remove predominantly only said non-exposed regions” during development, we mean that the non-exposed regions of the imageable layer and the corresponding regions of any underlying layers are selectively and preferentially removed by the processing solution, but not the exposed regions to any significant extent (there may be insubstantial removal of the exposed regions).

By “computer-to-press”, we mean the imaging means is carried out using a computer-directed imaging means (such as a laser) directly to the imageable layers without using masking or other intermediate imaging films.

Unless otherwise indicated, percentages refer to percents by dry weight, either the dry solids of a layer composition or formulation, or the dry coated weight of a layer (for example, imageable layer or topcoat). Unless otherwise indicated, the weight percent values can be interpreted as for either a layer formulation or a dried layer coating.

For clarification of definitions for any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any definitions explicitly set forth herein should be regarded as controlling.

Unless otherwise indicated, the term “polymer” refers to high and low molecular weight polymers including oligomers, homopolymers, and copolymers.

The term “copolymer” refers to polymers that are derived from two or more different monomers. That is, they comprise recurring units having at least two different chemical structures.

The term “backbone” refers to the chain of atoms in a polymer to which a plurality of pendant groups can be attached. An example of such a backbone is an “all carbon” backbone obtained from the polymerization of one or more ethylenically unsaturated polymerizable monomers. However, other backbones can include heteroatoms wherein the polymer is formed by a condensation reaction or some other means.

### Uses

The method of this invention is used primarily to provide lithographic printing plates that can be used in lithographic printing operations as described in more detail below. In general, the lithographic printing plate precursors comprise a substrate, an imageable layer, and an optional topcoat or outermost oxygen-barrier layer disposed over the imageable layer.

### Substrate

The lithographic printing plate precursors are formed by suitable application of an imageable layer formulation or composition onto a suitable substrate. This substrate can be an untreated or uncoated support but it is usually treated or coated in various ways as described below to provide a highly hydrophilic surface prior to application of the imageable layer composition. The substrate comprises a support that can be composed of any material that is conventionally used to prepare lithographic printing plate precursors. The substrate can be treated to provide an “interlayer” for improved adhesion or hydrophilicity, and the inner layer formulation is applied over the interlayer.

The substrate is usually in the form of a sheet, film, or foil, and is strong, stable, and flexible and resistant to dimensional change under conditions of use so that color records will register a full-color image. Typically, the support can be any self-supporting material including polymeric films (such as polyester, polyethylene, polycarbonate, cellulose ester polymer, and polystyrene films), glass, ceramics, metal sheets or foils, or stiff papers (including resin-coated and metallized papers), or a lamination of any of these materials (such as a lamination of an aluminum foil onto a polyester film). Metal supports include sheets or foils of aluminum, copper, zinc, titanium, and alloys thereof.

Polymeric film supports may be modified on one or both surfaces with a “subbing” layer to enhance hydrophilicity, or paper supports may be similarly coated to enhance planarity. Examples of subbing layer materials include but are not limited to, alkoxysilanes, amino-propyltriethoxysilanes, glycidioxypropyl-triethoxysilanes, and epoxy functional polymers, as well as conventional hydrophilic subbing materials used in silver halide photographic films (such as gelatin and other naturally occurring and synthetic hydrophilic colloids and vinyl polymers including vinylidene chloride copolymers).

A useful substrate is composed of an aluminum-containing support that may be coated or treated using techniques known in the art, including physical graining, electrochemical graining, chemical graining, and anodizing. For example, the aluminum sheet can be anodized using phosphonic acid or sulfuric acid using conventional procedures.

An optional interlayer may be formed by treatment of the aluminum support with, for example, a silicate, dextrine, calcium zirconium fluoride, hexafluorosilicic acid, phosphate/fluoride, poly(vinyl phosphonic acid) (PVPA), vinyl phosphonic acid-acrylic acid copolymer, poly(acrylic acid), or (meth)acrylic acid copolymer, or mixtures thereof. For example, the grained and/or sulfuric acid-anodized aluminum support can be treated with poly(phosphonic acid) using known procedures to improve surface hydrophilicity to provide a lithographic hydrophilic substrate.

The thickness of the substrate can be varied but should be sufficient to sustain the wear from printing and thin enough to wrap around a printing form. Such embodiments typically include a treated aluminum foil having a thickness of from about 100 to about 600 μm.

The backside (non-imaging side) of the substrate may be coated with antistatic agents and/or slipping layers or a matte layer to improve handling and “feel” of the imageable element.

The substrate can also be a cylindrical surface having the imageable layers applied thereon, and thus be an integral part of the printing press or a sleeve that is incorporated onto a press cylinder. The use of such imaged cylinders is described for example in U.S. Pat. No. 5,713,287 (Gelbart).

### Imageable Layer Composition

The imageable layer used in the lithographic printing plate precursors is generally composed of a radiation-sensitive composition having several components. For example, the radiation-sensitive composition (and imageable layer) comprises one or more free radically polymerizable components, each of which contains one or more free radically polymerizable groups that can be polymerized using free radical initiation. For example, such free radically polymerizable components can contain one or more free radical polymerizable monomers or oligomers having one or more addition polymerizable ethylenically unsaturated groups, crosslinkable ethylenically unsaturated groups, ring-opening polymerizable groups, azido groups, aryldiazonium salt groups, aryldiazosulfonate groups, or a combination thereof. Similarly, crosslinkable polymers having such free radically polymerizable groups can also be used.

Suitable ethylenically unsaturated compounds that can be polymerized or crosslinked include ethylenically unsaturated polymerizable monomers that have one or more of the polymerizable groups, including unsaturated esters of alcohols, such as acrylate and methacrylate esters of polyols. Oligomers and/or prepolymers, such as urethane acrylates and methacrylates, epoxide acrylates and methacrylates, polyester acrylates and methacrylates, polyether acrylates and methacrylates, and unsaturated polyester resins can also be used. In some embodiments, the secondary free radically polymerizable component comprises carboxy groups.

Useful free radically polymerizable components include free-radical polymerizable monomers or oligomers that comprise addition polymerizable ethylenically unsaturated groups including multiple acrylate and methacrylate groups and combinations thereof, or free-radical crosslinkable polymers. Free radically polymerizable compounds include those derived from urea urethane (meth)acrylates or urethane (meth)acrylates having multiple polymerizable groups. For example, a free radically polymerizable component can be prepared by reacting DESMODUR® N100 aliphatic polyisocyanate resin based on hexamethylene diisocyanate (Bayer Corp., Milford, Conn.) with hydroxyethyl acrylate and pentaerythritol triacrylate. Useful free radically polymerizable compounds include NK Ester A-DPH (dipentaerythritol hexaacrylate) that is available from Kowa American, and Sartomer 399 (dipentaerythritol pentaacrylate), Sartomer 355 (di-trimethylolpropane tetraacrylate), Sartomer 295 (pentaerythritol tetraacrylate), Sartomer 415 [ethoxylated (20)trimethylolpropane triacrylate], Sartomer 480 [ethoxylated (10) bisphenol A dimethacrylate], and Sartomer 499 [ethoxylated (6) trimethylolpropane triacrylate] that are available from Sartomer Company, Inc.

Other useful free radically polymerizable components include those described in copending and commonly assigned U.S. Ser. No. 11/949,810 (filed Dec. 4, 2007 by Bauman, Dwars, Strehmel, Simpson, Savariar-Hauck, and Hauck) that include 1H-tetrazole groups. This copending application is incorporated herein by reference with respect to these components.

Numerous other free radically polymerizable compounds are known to those skilled in the art and are described in considerable literature including Photoreactive Polymers: The Science and Technology of Resists, A Reiser, Wiley, New York, 1989, pp. 102-177, by B. M. Monroe in Radiation Curing: Science and Technology, S. P. Pappas, Ed., Plenum, N.Y., 1992, pp. 399-440, and in “Polymer Imaging” by A. B. Cohen and P. Walker, in Imaging Processes and Material, J. M. Sturge et al. (Eds.), Van Nostrand Reinhold, New York, 1989, pp. 226-262. For example, useful free radically polymerizable components are also described in EP 1,182,033A1 (noted above), beginning with paragraph [0170], and in U.S. Pat. No. 6,309,792 (Hauck et al.), U.S. Pat. No. 6,569,603 (Furukawa), and U.S. Pat. No. 6,893,797 (Munnelly et al.).

The free radically polymerizable component can be present in the radiation-sensitive composition (imageable layer) at a weight ratio to the primary polymeric binder (described below) of from about 5:95 to about 95:5, from about 10:90 to about 90:10, or from about 30:70 to about 70:30. For example, the free radically polymerizable component can be present in an amount of at least 10 and up to and including 70% based on the total solids in the radiation sensitive composition, or the total dry weight of the imageable layer.

The imageable layer (or radiation-sensitive composition) also includes an initiator composition that is capable of generating free radicals sufficient to initiate polymerization of all the various free radically polymerizable components upon exposure of the composition to imaging radiation, and in the presence of a suitable radiation absorbing compound (described below). The initiator composition is generally responsive to electromagnetic imaging radiation in the ultraviolet, visible, infrared, or near infrared spectral regions, corresponding to the spectral range of at least 150 nm and up to and including 1500 nm. For example, they can be responsive to infrared radiation of at least 700 nm and up to and including 1400 nm (for example from about 750 to about 1250 nm). Other initiator compositions are responsive to “violet” radiation of from about 250 to about 425 nm. Initiator compositions are used that are appropriate for the desired imaging wavelength(s).

In general, suitable initiator compositions comprise compounds that include but are not limited to, amines (such as alkanol amines), thiol compounds, anilinodiacetic acids or derivatives thereof, N-phenyl glycine and derivatives thereof, N,N-dialkylaminobenzoic acid esters, N-arylglycines and derivatives thereof (such as N-phenylglycine), aromatic sulfonylhalides, trihalogenomethylsulfones, imides (such as N-benzoyloxyphthalimide), diazosulfonates, 9,10-dihydroanthracene derivatives, N-aryl, S-aryl, or O-aryl polycarboxylic acids with at least 2 carboxy groups of which at least one is bonded to the nitrogen, oxygen, or sulfur atom of the aryl moiety (such as aniline diacetic acid and derivatives thereof and other “co-initiators” described in U.S. Pat. No. 5,629,354 of West et al.), oxime ethers and oxime esters (such as those derived from benzoin), α-hydroxy or α-amino-acetophenones, alkyltriarylborates, trihalogenomethylarylsulfones, benzoin ethers and esters, triaryloxazoles, coumarins, stilbenyl derivatives, peroxides (such as benzoyl peroxide), hydroperoxides (such as cumyl hydroperoxide), azo compounds (such as azo bis-isobutyronitrile), 2,4,5-triarylimidazolyl dimers (also known as hexaarylbiimidazoles, or “HABI's”) as described for example in U.S. Pat. No. 4,565,769 (Dueber et al.), boron-containing compounds (such as tetraarylborates and alkyltriarylborates) and organoborate salts such as those described in U.S. Pat. No. 6,562,543 (Ogata et al.), and onium salts (such as ammonium salts, diaryliodonium salts, triarylsulfonium salts, aryldiazonium salts, and N-alkoxypyridinium salts). Other known initiator composition components are described for example in U.S. Patent Application Publication 2003/0064318 (noted above).

Co-initiators can also be used, such as metallocenes (such as titanocenes and ferrocenes), polycarboxylic acids, haloalkyl triazines, thiols, or mercaptans (such as mercaptotriazoles), borate salts, and photooxidants containing a heterocyclic nitrogen that is substituted by an alkoxy or acyloxy group, as described in U.S. Pat. No. 5,942,372 (West et al.).

In some embodiments, useful initiator compositions include a combination of a 2,4,5-triarylimidazolyl dimer and a thiol compound such as either 2,2′-bis(o-chlorophenyl)-4,4′, 5,5′-tetraphenylbiimidazole or 2,2′-bis(o-chlorophenyl)-4,4′,5,5′-tetra(m-methoxyphenyl)biimidazole in combination with a thiol compound such as a mercaptotriazole.

Useful imageable elements (and radiation-sensitive compositions) include an onium salt including but not limited to, a sulfonium, oxysulfoxonium, oxysulfonium, sulfoxonium, ammonium, selenonium, arsonium, phosphonium, diazonium, or halonium salt. Further details of useful onium salts, including representative examples, are provided in U.S. Patent Application Publication 2002/0068241 (Oohashi et al.), WO 2004/101280 (Munnelly et al.), and U.S. Pat. No. 5,086,086 (Brown-Wensley et al.), U.S. Pat. No. 5,965,319 (Kobayashi), and U.S. Pat. No. 6,051,366 (Baumann et al.). For example, suitable phosphonium salts include positive-charged hypervalent phosphorus atoms with four organic substituents. Suitable sulfonium salts such as triphenylsulfonium salts include a positively-charged hypervalent sulfur with three organic substituents. Suitable diazonium salts possess a positive-charged azo group (that is —N═N⁺). Suitable ammonium salts include a positively-charged nitrogen atom such as substituted quaternary ammonium salts with four organic substituents, and quaternary nitrogen heterocyclic rings such as N-alkoxypyridinium salts. Suitable halonium salts include a positively-charged hypervalent halogen atom with two organic substituents. The onium salts generally include a suitable number of negatively-charged counterions such as halides, hexafluorophosphate, thiosulfate, hexafluoroantimonate, tetrafluoroborate, sulfonates, hydroxide, perchlorate, n-butyltriphenyl borate, tetraphenyl borate, and others readily apparent to one skilled in the art.

The halonium salts are useful such as the iodonium salts. In one embodiment, the onium salt has a positively-charged iodonium, (4-methylphenyl)[4-(2-methylpropyl)phenyl]-moiety and a suitable negatively charged counterion. A representative example of such an iodonium salt is available as Irgacure® 250 from Ciba Specialty Chemicals (Tarrytown, N.Y.) that is (4-methylphenyl)[4-(2-methylpropyl)phenyl]iodonium hexafluorophosphate and is supplied in a 75% propylene carbonate solution.

Useful boron-containing compounds include organic boron salts that include an organic boron anion such as those described in the noted U.S. Pat. No. 6,569,603 that is paired with a suitable cation such as an alkali metal ion, an onium, or a cationic sensitizing dye. Useful onium cations for this purpose include but are not limited to, ammonium, sulfonium, phosphonium, iodonium, and diazonium cations. Iodonium salts such as iodonium borates are useful as initiator compounds in radiation-sensitive compounds that are designed for “on-press” development (described in more detail below). They may be used alone or in combination with various co-initiators such as heterocyclic mercapto compounds including mercaptotriazoles, mercaptobenzimidazoles, mercaptobenzoxazoles, mercaptobenzothiazoles, mercaptobenzoxadiazoles, mercaptotetrazoles, such as those described for example in U.S. Pat. No. 6,884,568 (Timpe et al.) in amounts of at least 0.5 and up to and including 10 weight % based on the total solids of the radiation-sensitive composition. Useful mercaptotriazoles include 3-mercapto-1,2,4-triazole, 4-methyl-3-mercapto-1,2,4-triazole, 5-mercapto-1-phenyl-1,2,4-triazole, 4-amino-3-mercapto-1,2,4-triazole, 3-mercapto-1,5-diphenyl-1,2,4-triazole, and 5-(p-aminophenyl)-3-mercapto-1,2,4-triazole.

Examples of other useful initiator compositions are described for example in EP 1,182,033 (Fujimaki et al.) and in U.S. Pat. No. 6,352,812 (Shimazu et al.) and U.S. Pat. No. 6,893,797 (Munnelly et al.).

One class of useful iodonium cations include diaryliodonium cations that are represented by the following Structure (IB):

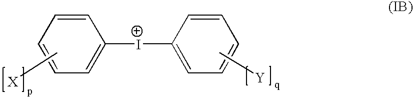

wherein X and Y are independently halo groups (for example, fluoro, chloro, or bromo), substituted or unsubstituted alkyl groups having 1 to 20 carbon atoms (for example, methyl, chloromethyl, ethyl, 2-methoxyethyl, n-propyl, isopropyl, isobutyl, n-butyl, t-butyl, all branched and linear pentyl groups, 1-ethylpentyl, 4-methylpentyl, all hexyl isomers, all octyl isomers, benzyl, 4-methoxybenzyl, p-methylbenzyl, all dodecyl isomers, all icosyl isomers, and substituted or unsubstituted mono-and poly-, branched and linear haloalkyls), substituted or unsubstituted alkyloxy having 1 to 20 carbon atoms (for example, substituted or unsubstituted methoxy, ethoxy, isopropoxy, t-butoxy, (2-hydroxytetradecyl)oxy, and various other linear and branched alkyleneoxyalkoxy groups), substituted or unsubstituted aryl groups having 6 or 10 carbon atoms in the carbocyclic aromatic ring (such as substituted or unsubstituted phenyl and naphthyl groups including mono- and polyhalophenyl and naphthyl groups), or substituted or unsubstituted cycloalkyl groups having 3 to 8 carbon atoms in the ring structure (for example, substituted or unsubstituted cyclopropyl, cyclopentyl, cyclohexyl, 4-methylcyclohexyl, and cyclooctyl groups). Typically, X and Y are independently substituted or unsubstituted alkyl groups having 1 to 8 carbon atoms, alkyloxy groups having 1 to 8 carbon atoms, or cycloalkyl groups having 5 or 6 carbon atoms in the ring, and more preferably, X and Y are independently substituted or unsubstituted alkyl groups having 3 to 6 carbon atoms (and particularly branched alkyl groups having 3 to 6 carbon atoms). Thus, X and Y can be the same or different groups, the various X groups can be the same or different groups, and the various Y groups can be the same or different groups. Both “symmetric” and “asymmetric” diaryliodonium borate compounds are contemplated but the “symmetric” compounds are preferred (that is, they have the same groups on both phenyl rings).

In addition, two or more adjacent X or Y groups can be combined to form a fused carbocyclic or heterocyclic ring with the respective phenyl groups.

The X and Y groups can be in any position on the phenyl rings but typically they are at the 2- or 4-positions on either or both phenyl rings.

Despite what type of X and Y groups are present in the iodonium cation, the sum of the carbon atoms in the X and Y substituents generally is at least 6, and typically at least 8, and up to 40 carbon atoms. Thus, in some compounds, one or more X groups can comprise at least 6 carbon atoms, and Y does not exist (q is 0). Alternatively, one or more Y groups can comprise at least 6 carbon atoms, and X does not exist (p is 0). Moreover, one or more X groups can comprise less than 6 carbon atoms and one or more Y groups can comprise less than 6 carbon atoms as long as the sum of the carbon atoms in both X and Y is at least 6. Still again, there may be a total of at least 6 carbon atoms on both phenyl rings.

In Structure IB, p and q are independently 0 or integers of 1 to 5, provided that either p or q is at least 1. Typically, both p and q are at least 1, or each of p and q is 1. Thus, it is understood that the carbon atoms in the phenyl rings that are not substituted by X or Y groups have a hydrogen atom at those ring positions.

Useful boron-containing anions are organic anions having four organic groups attached to the boron atom. Such organic anions can be aliphatic, aromatic, heterocyclic, or a combination of any of these. Generally, the organic groups are substituted or unsubstituted aliphatic or carbocyclic aromatic groups. For example, useful boron-containing anions can be represented by the following Structure (IB_{Z}):

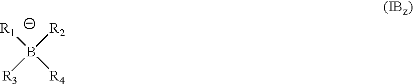

wherein R₁, R₂, R₃, and R₄ are independently substituted or unsubstituted alkyl groups having 1 to 12 carbon atoms (such as methyl, ethyl, n-propyl, isopropyl, n-butyl, isobutyl, t-butyl, all pentyl isomers, 2-methylpentyl, all hexyl isomers, 2-ethylhexyl, all octyl isomers, 2,4,4-trimethylpentyl, all nonyl isomers, all decyl isomers, all undecyl isomers, all dodecyl isomers, methoxymethyl, and benzyl) other than fluoroalkyl groups, substituted or unsubstituted carbocyclic aryl groups having 6 to 10 carbon atoms in the aromatic ring (such as phenyl, p-methylphenyl, 2,4-methoxyphenyl, naphthyl, and pentafluorophenyl groups), substituted or unsubstituted alkenyl groups having 2 to 12 carbon atoms (such as ethenyl, 2-methylethynyl, allyl, vinylbenzyl, acryloyl, and crotonotyl groups), substituted or unsubstituted alkynyl groups having 2 to 12 carbon atoms (such as ethynyl, 2-methylethynyl, and 2,3-propynyl groups), substituted or unsubstituted cycloalkyl groups having 3 to 8 carbon atoms in the ring structure (such as cyclopropyl, cyclopentyl, cyclohexyl, 4-methylcyclohexyl, and cyclooctyl groups), or substituted or unsubstituted heterocyclyl groups having 5 to 10 carbon, oxygen, sulfur, and nitrogen atoms (including both aromatic and non-aromatic groups, such as substituted or unsubstituted pyridyl, pyrimidyl, furanyl, pyrrolyl, imidazolyl, triazolyl, tetrazoylyl, indolyl, quinolinyl, oxadiazolyl, and benzoxazolyl groups). Alternatively, two or more of R₁, R₂, R₃, and R₄ can be joined together to form a heterocyclic ring with the boron atom, such rings having up to 7 carbon, nitrogen, oxygen, or nitrogen atoms. None of the R₁ through R₄ groups contains halogen atoms and particularly fluorine atoms.

Typically, R₁, R₂, R₃, and R₄ are independently substituted or unsubstituted alkyl or aryl groups as defined above, and more typically, at least 3 of R₁, R₂, R₃, and R₄ are the same or different substituted or unsubstituted aryl groups (such as substituted or unsubstituted phenyl groups). For example, all of R₁, R₂, R₃, and R₄ can be the same or different substituted or unsubstituted aryl groups, or all of the groups are the same substituted or unsubstituted phenyl group. Z^{—} can be a tetraphenyl borate wherein the phenyl groups are substituted or unsubstituted (for example, all are unsubstituted phenyl groups).

Some representative iodonium borate compounds include but are not limited to, 4-octyloxyphenyl phenyliodonium tetraphenylborate, [4-[(2-hydroxytetradecyl)-oxy]phenyl]phenyliodonium tetraphenylborate, bis(4-t-butylphenyl)iodonium tetraphenylborate, 4-methylphenyl-4′-hexylphenyliodonium tetraphenylborate, 4-methylphenyl-4′-cyclohexylphenyliodonium tetraphenylborate, bis(t-butylphenyl)iodonium tetrakis(pentafluorophenyl)borate, 4-hexylphenyl-phenyliodonium tetraphenylborate, 4-methylphenyl-4′-cyclohexylphenyliodonium n-butyltriphenylborate, 4-cyclohexylphenyl-4′-phenyliodonium tetraphenylborate, 2-methyl-4-t-butylphenyl-4′-methylphenyliodonium tetraphenylborate, 4-methylphenyl-4′-pentylphenyliodonium tetrakis[3,5-bis(trifluoromethyl)phenyl]-borate, 4-methoxyphenyl-4′-cyclohexylphenyliodonium tetrakis(penta-fluorophenyl)borate, 4-methylphenyl-4′-dodecylphenyliodonium tetrakis(4-flurophenyl)borate, bis(dodecylphenyl)iodonium tetrakis(pentafluorophenyl)-borate, and bis(4-t-butylphenyl)iodonium tetrakis(1-imidazolyl)borate. Mixtures of two or more of these compounds can also be used in the iodonium borate initiator composition.

Such diaryliodonium borate compounds can be prepared, in general, by reacting an aryl iodide with a substituted or unsubstituted arene, followed by an ion exchange with a borate anion. Details of various preparatory methods are described in U.S. Pat. No. 6,306,555 (Schulz et al.), and references cited therein, and by Crivello, J. Polymer Sci., Part A: Polymer Chemistry, 37, 4241-4254 (1999), both of which are incorporated herein by reference.

The boron-containing anions can also be supplied as part of infrared radiation absorbing dyes (for example, cationic dyes) as described below. Such boron-containing anions generally are defined as described above with Structure (IBz).

The free radical generating compounds in the initiator composition are generally present in the imageable layer (and radiation-sensitive composition) in an amount of at least 0.5% and up to and including 30%, and typically at least 2 and up to and including about 20%, based on composition total solids or total dry weight of the imageable layer. The optimum amount of the various initiator components may differ for various compounds and the sensitivity of the radiation-sensitive composition that is desired and would be readily apparent to one skilled in the art.

The imageable element also includes one or more imaging radiation absorbing compounds (or chromophores or sensitizers) that spectrally sensitize the composition to a desired wavelength. In some embodiments, this imparted sensitivity is at a λₘₐₓ of from about 250 nm and up to and 500 nm, typically from about 350 to about 475 nm and more typically from about 390 to about 430 nm. For example, useful sensitizers for these wavelengths include but are not limited to compounds having the following Formula:

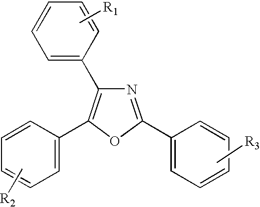

wherein R₁, R₂ and R₃ independently represent a hydrogen atom, alkyl, aryl or aralkyl group that may be substituted, an —NR₄R₅-group (R₄ and R₅ representing an alkyl, aryl or aralkyl group), or —OR₆ group (R₆ representing an alkyl, aryl or aralkyl group). Particularly useful compounds of this Formula contain at least one of substituent R₁, R₂, and R₃ that represents a donor group, such as an amino group (for example, an dialkylamino group). Such compounds are described for example in WO 2004/074930 (Baumann et al.). These compounds can be made following the procedure given in DE 1,120,875 (Sues et al.) and EP 129,059 (Hayashida).

Other embodiments include infrared radiation absorbing compounds (“IR absorbing compounds”) that generally absorb radiation at a λₘₐₓ of from about 700 to about 1400 nm and typically from about 750 to about 1250 nm with minimal absorption at 300 to 600 nm.

Examples of suitable IR dyes include but are not limited to, azo dyes, squarylium dyes, triarylamine dyes, thioazolium dyes, indolium dyes, oxonol dyes, oxazolium dyes, cyanine dyes, merocyanine dyes, phthalocyanine dyes, indocyanine dyes, indotricarbocyanine dyes, hemicyanine dyes, streptocyanine dyes, oxatricarbocyanine dyes, thiocyanine dyes, thiatricarbocyanine dyes, merocyanine dyes, cryptocyanine dyes, naphthalocyanine dyes, polyaniline dyes, polypyrrole dyes, polythiophene dyes, chalcogenopyryloarylidene and bi(chalcogenopyrylo)- polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, polymethine dyes, squaraine dyes, oxazole dyes, croconine dyes, porphyrin dyes, and any substituted or ionic form of the preceding dye classes. Suitable dyes are described for example, in U.S. Pat. No. 4,973,572 (DeBoer), U.S. Pat. No. 5,208,135 (Patel et al.), U.S. Pat. No. 5,244,771 (Jandrue Sr. et al.), and U.S. Pat. No. 5,401,618 (Chapman et al.), and EP 0 823 327A1 (Nagasaka et al.).

Cyanine dyes having an anionic chromophore are also useful. For example, the cyanine dye may have a chromophore having two heterocyclic groups. In another embodiment, the cyanine dye may have at least two sulfonic acid groups, more particularly two sulfonic acid groups and two indolenine groups. Useful IR-sensitive cyanine dyes of this type are described for example in U.S. Patent Application Publication 2005-0130059 (Tao). A general description of one class of suitable cyanine dyes is shown by the formula in paragraph 0026 of WO 2004/101280 (Munnelly et al.).

In addition to low molecular weight IR-absorbing dyes, IR dye moieties bonded to polymers can be used as well. Moreover, IR dye cations can be used as well, that is, the cation is the IR absorbing portion of the dye salt that ionically interacts with a polymer comprising carboxy, sulfo, phospho, or phosphono groups in the side chains.

Near infrared absorbing cyanine dyes are also useful and are described for example in U.S. Pat. No. 6,309,792 (Hauck et al.), U.S. Pat. No. 6,264,920 (Achilefu et al.), U.S. Pat. No. 6,153,356 (Urano et al.), and U.S. Pat. No. 5,496,903 (Watanabe et al.). Suitable dyes may be formed using conventional methods and starting materials or obtained from various commercial sources including American Dye Source (Baie D'Urfe, Quebec, Canada) and FEW Chemicals (Germany). Other useful dyes for near infrared diode laser beams are described, for example, in U.S Pat. No. 4,973,572 (noted above).

Useful IR absorbing compounds include various pigments including carbon blacks such as carbon blacks that are surface-functionalized with solubilizing groups are well known in the art. Carbon blacks that are grafted to hydrophilic, nonionic polymers, such as FX-GE-003 (manufactured by Nippon Shokubai), or which are surface-functionalized with anionic groups, such as CAB-O-JET® 200 or CAB-O-JET® 300 (manufactured by the Cabot Corporation) are also useful. Other useful pigments include, but are not limited to, Heliogen Green, Nigrosine Base, iron (III) oxides, manganese oxide, Prussian Blue, and Paris Blue. The size of the pigment particles should not be more than the thickness of the imageable layer.

The radiation absorbing compound is generally present in the imageable element in an amount of at least 0.5% and up to 30 weight % and typically from about 3 to about 25 weight % (based on total dry layer weight). The particular amount needed for this purpose would be readily apparent to one skilled in the art, depending upon the specific compound used and the properties of the processing solution to be used.

The primary polymeric binder useful in the radiation-sensitive composition (and imageable layer) are polymers having a hydrophobic backbone that comprises recurring units derived from one or more different ethylenically unsaturated polymerizable monomers as long as some of those recurring units have pendant polyetheramine side chains. Such recurring units are present in the primary polymeric binder in an amount of at least 1 mol % based on the total recurring units in the primary polymeric binder. In other embodiments, such recurring units are present in an amount of from about 1 to about 50 mol % based on the total primary polymer binder recurring units. In most embodiments, the recurring units comprising polyetheramine side chains are derived from one or more (meth)acrylamides having the appropriate alkylene oxide segments connected to the pendant amide group. Thus, the primary polymeric binders can be formed from one or more radically polymerizable ethylenically unsaturated monomers.

For example such primary polymeric binders generally have polyetheramine side chains that comprise at least 5 alkylene oxide segments, such as ethylene oxide, propylene oxide, and butylene oxide segments. In some embodiments, the polyetheramine side chains comprise from 5 to 90 alkylene oxide segments, such as from 5 to 90 ethylene oxide segments, or typically from 10 to 50, or more typically from 30 to 50, alkylene oxide segments. Such polyetheramine side chains generally have a molecular weight of at least 600, or typically at least 1000 or at least 1500.

For example, the primary polymeric binder can comprise recurring units represented by the following Structure (PB):

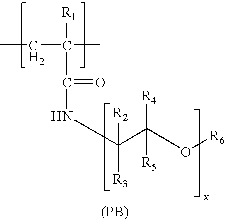

wherein x is from 5 to 90, or typically from 10 to 50, and R₁ to R₆ are independently hydrogen or a substituted or unsubstituted alkyl group having 1 to 6 carbon atoms (such as methyl, ethyl, n-propyl, iso-propyl, and t-butyl) that may be the same or different in each recurring unit. Thus, each of R₁ to R₆ can vary from one recurring unit to another in the same primary polymeric binder. Such recurring units (PB) can comprise at least 1 and up to 50 mol % of all recurring units in the polymeric binder. R₆ is usually methyl.

In some embodiments, the primary polymeric binder can be represented by the following Structure (PB-1):

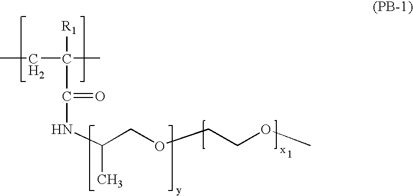

wherein x₁ is from 1 to 31 and y is from 4 to 10.

In still other embodiments, the polymeric binder can be represented by the following Structure (IA):

-(A)ᵣ-(B)ₛ—(C)ₜ-(D)_{w}- (IA)

wherein A represents recurring units having said polyetheramine side chains comprising from 5 to 90 alkylene oxide segments, B represents recurring units comprising pendant cyano groups, C represents recurring units having pendant acidic groups, and D represents recurring units other than those represented by A, B, and C, r is from about 1 to about 30 mol % (typically from about 5 to about 20 mol %), s is from about 10 to about 80 mol % (from about 30 to about 75 mol %), t is from about 1 to about 30 mol % (from about 1 to about 15 mol %), and w is from 0 to about 50 mol % (from 0 to about 25 mol %).

The B recurring units are generally derived from one or more of (meth)acrylonitrile, cyanostyrenes, or cyano(meth)acrylates. The (meth)acrylonitriles are particularly useful.

The C recurring units comprise one or more acidic groups such as carboxy, phosphoric acid, and sulfonic acid, as well as salts thereof (carboxylates, sulfonates, etc.). Monomers from such recurring units can be derived include but are not limited to, carboxy-containing vinyl monomers, carboxylated styrenes, and sulfated styrenes. Ethylenically unsaturated polymerizable monomers that have carboxy groups, or that have reactive groups that can be converted to carboxy groups, or to which carboxy groups can be attached after polymerization, are particularly useful. Thus, the carboxy groups can be obtained from a number of synthetic methods. Useful monomers having pendant carboxylic acid groups include but are not limited to, (meth)acrylic acid, 4-carboxyphenyl (meth)acrylate, and 4-carboxystyrene.

The D recurring units are derived from one or more of vinyl carbazole or vinyl carbazole derivatives as described in U.S. Pat. No. 7,175,949 (Tao et al.), alkyl (meth)acrylates [such as methyl (meth)acrylates], (meth)acrylamides, N-phenyl maleimides, poly(alkylene glycol) methyl ether (meth)acrylates [such as poly(ethylene glycol) methyl ether (meth)acrylates], and styrene monomers such as substituted and unsubstituted styrene. Useful combinations of D recurring units include a combination of recurring units derived from two or more of a methyl (meth)acrylate, an N-vinyl carbazole, and a polyethylene glycol methyl ether (meth)acrylate. These are merely provided as examples and not intended to be limiting since a skilled artisan could use many other ethylenically unsaturated polymerizable monomers.

In some embodiments, the A recurring units are derived from recurring units containing the noted polyetheramine pendant groups, the B recurring units are derived from one or more of (meth)acrylonitrile, the C recurring units are derived from one or more of (meth)acrylic acid, 4-carboxyphenyl (meth)acrylate, and 4-carboxystyrene, and the D recurring units are derived from one or more of vinyl carbazole, methyl (meth)acrylate, poly(ethylene glycol) methyl ether (meth)acrylate, and a styrene monomer.

The primary polymeric binder is present in the imageable element as discrete particles generally having an average diameter of from about 30 to about 2000 nm, or typically from about 60 to about 1000 nm, or from about 60 and 500 nm. Thus, these polymeric binders are in particulate form, meaning that they exist at room temperature as discrete particles, for example in an aqueous dispersion.

Thus, in some embodiments, the imageable element comprises a primary polymeric binder that is present as discrete particles having an average diameter of from about 60 to about 500 nm and comprises polyetheramine side chains connected to a backbone, wherein the polyetheramine side chains comprise from 5 to 90 alkylene oxide segments.

The primary polymeric binders useful in this invention can be prepared using conventional starting materials and reaction conditions, as illustrated for example in the synthetic preparations shown below prior to the Examples.

The primary polymeric binder is generally present in the dry radiation-sensitive composition or imageable layer in an amount of from about 5 to about 70%, or typically from about 10 to about 40%, based on total dry weight.

The primary polymeric binders can be prepared using known starting materials (monomers) and conventional polymerization conditions. The preparation of representative primary polymeric is described below before the Examples.

The imageable layer (and radiation-sensitive composition) can comprise one or more secondary polymeric binders in an amount of from about 25 to about 75%, based on the total composition (or imageable layer) dry weight.

The secondary polymeric binders can be radically polymerizable polymeric binders. These polymeric binders can be “self-crosslinkable”, by which we mean that a separate free radically polymerizable component is not necessary. Such binders have a backbone comprising multiple (at least two) urethane moieties. In some embodiments, there are at least two of these urethane moieties in each backbone recurring unit. The primary polymeric binders also include side chains attached to the backbone, which side chains include one or more free radically polymerizable groups (such as ethylenically unsaturated groups) that can be polymerized (crosslinked) in response to free radicals produced by the initiator composition (described below). There may be at least two of these side chains per molecule.

The free radically polymerizable groups (or ethylenically unsaturated groups) can be part of aliphatic or aromatic acrylate side chains attached to the polymeric backbone. Generally, there are at least 2 and up to 20 such groups per molecule, or typically from 2 to 10 such groups per molecule.

The secondary polymeric binders can also comprise hydrophilic groups including but not limited to, carboxy, sulfo, or phospho groups, either attached directly to the backbone or attached as part of side chains other than the free radically polymerizable side chains. In most embodiments, the hydrophilic groups, such as carboxy groups, are directly attached to the backbone.

Useful commercial products that comprise secondary polymeric binders useful in this invention include but are not limited to, Bayhydrol® UV VP LS 2280, Bayhydrol® UV VP LS 2282, Bayhydrol® UV VP LS 2317, Bayhydrol® UV VP LS 2348, and Bayhydrol® UV XP 2420, that are all available from Bayer MaterialScience, as well as Laromer™ LR 8949, Laromer™ LR 8983, and Laromer™ LR 9005, that are all available from BASF.

Other useful secondary polymeric binders include poly(urethane-acrylic) hybrids. This hybrid has a molecular weight of from about 50,000 to about 500,000. These hybrids can be either “aromatic” or “aliphatic” in nature depending upon the specific reactants used in their manufacture. Blends of two or more poly(urethane-acrylic) hybrids can also be used.

Some poly(urethane-acrylic) hybrids are commercially available in dispersions from Air Products and Chemicals, Inc. (Allentown, Pa.), for example, as the Hybridur® 540, 560, 570, 580, 870, 878, 880 polymer dispersions. Further details about each commercial Hybridur® polymer dispersion can be obtained by visiting the Air Products and Chemicals, Inc. website.

Still other useful secondary polymeric binders are polymers having polyalkylene oxide segments [such as poly(ethylene) oxide and poly(propylene) oxide segments] as described for example in U.S. Pat. No. 6,899,994 (Huang et al.) and U.S. Pat. No. 7,261,998 (Hayashi et al.) that are incorporated herein by reference for specific details about such polymers and methods of preparing them. Particular details of such polymeric binders are provided in Columns 6-13 of the noted Huang et al. patent and Columns 7-13 of the noted Hayashi et al. patent.

Such secondary polymeric binders include but are not limited to, (meth)acrylic acid and acid ester resins [such as (meth)acrylates], polyvinyl acetals, phenolic resins, polymers derived from styrene, N-substituted cyclic imides or maleic anhydrides, such as those described in EP 1,182,033A1 (Fujimaki et al.) and U.S. Pat. No. 6,309,792 (Hauck et al.), U.S. Pat. No. 6,352,812 (Shimazu et al.), U.S. Pat. No. 6,569,603 (Furukawa et al.), and U.S. Pat. No. 6,893,797 (Munnelly et al.). Also useful are the vinyl carbazole polymers described in U.S. Pat. No. 7,175,949 (Tao et al.), and the polymers having pendant vinyl groups as described in U.S. Pat. No. 7,279,255 (Tao et al.). Copolymers of polyethylene glycol methacrylate/acrylonitrile/styrene in particulate form, dissolved copolymers derived from carboxyphenyl methacrylamide/acrylonitrile/methacrylamide/N-phenyl maleimide, copolymers derived from polyethylene glycol methacrylate/acrylonitrile/vinyl carbazole/styrene/methacrylic acid, copolymers derived from N-phenyl maleimide/methacrylamide/methacrylic acid, copolymers derived from acrylonitrile/methacrylamide/N-phenyl maleimide/acrylic acid, copolymers derived from urethane-acrylic intermediate A (the reaction product of p-toluene sulfonyl isocyanate and hydroxyl ethyl methacrylate)/acrylonitrile/N-phenyl maleimide, and copolymers derived from N-methoxymethyl methacrylamide/methacrylic acid/acrylonitrile/n-phenylmaleimide are useful.

The imageable layer (radiation-sensitive composition) can further comprise one or more phosphate (meth)acrylates, each of which has a molecular weight generally greater than 200 and typically at least 300 and up to and including 1000. By “phosphate (meth)acrylate” we also mean to include “phosphate methacrylates” and other derivatives having substituents on the vinyl group in the acrylate moiety. Such compounds and their use in imageable layers are described in more detail in U.S. Pat. No. 7,175,969 (Ray et al.) that is incorporated herein by reference.

Representative phosphate (meth)acrylates include but are not limited to, ethylene glycol methacrylate phosphate (available from Aldrich Chemical Co.), a phosphate of 2-hydroxyethyl methacrylate that is available as Kayamer PM-2 from Nippon Kayaku (Japan), a phosphate of a di(caprolactone modified 2-hydroxyethyl methacrylate) that is available as Kayamer PM-21 (Nippon Kayaku, Japan), and a polyethylene glycol methacrylate phosphate with 4-5 ethoxy groups that is available as Phosmer M, Phosmer MH, Phosmer PE, Phosmer PEH, Phosmer PP. and Phosmer PPH from Uni-Chemical Co., Ltd. (Japan).

The phosphate (meth)acrylate can be present in the imageable layer in an amount of at least 0.5 and up to and including 20% and typically at least 0.9 and up to and including 10%, based on total dry layer weight.

The imageable layer can also include a “primary additive” that is a poly(alkylene glycol) or an ether or ester thereof that has a molecular weight of at least 200 and up to and including 4000. This primary additive can be present in an amount of at least 2 and up to and including 50 weight %, based on the total dry weight of the imageable layer. Useful primary additives include, but are not limited to, one or more of polyethylene glycol, polypropylene glycol, polyethylene glycol methyl ether, polyethylene glycol dimethyl ether, polyethylene glycol monoethyl ether, polyethylene glycol diacrylate, ethoxylated bisphenol A di(meth)acrylate, and polyethylene glycol mono methacrylate. Also useful are Sartomer SR 9036 (ethoxylated (30) bisphenol A dimethacrylate), CD 9038 (ethoxylated (30) bisphenol A diacrylate), SR 399 (dipentaerythritol pentaacrylate), and Sartomer SR 494 (ethoxylated (5) pentaerythritol tetraacrylate), and similar compounds all of which that can be obtained from Sartomer Company, Inc. In some embodiments, the primary additive may be “non-reactive” meaning that it does not contain polymerizable vinyl groups.

The imageable layer can also include a “secondary additive” that is a poly(vinyl alcohol), a poly(vinyl pyrrolidone), poly(vinyl imidazole), or polyester in an amount of up to and including 20 weight % based on the total dry weight of the imageable layer.

The imageable layer can also include a variety of optional compounds including but not limited to, colorants and colorant precursors, color developers, dispersing agents, humectants, biocides, plasticizers, surfactants for coatability or other properties, viscosity builders, pH adjusters, drying agents, defoamers, preservatives, antioxidants, development aids, rheology modifiers or combinations thereof, or any other addenda commonly used in the lithographic art, in conventional amounts. Useful viscosity builders include hydroxypropyl cellulose, hydroxyethyl cellulose, carboxymethyl cellulose, and poly(vinyl pyrrolidones).

The radiation-sensitive composition can be applied to a substrate as a solution or dispersion in a coating liquid using any suitable equipment and procedure, such as spin coating, knife coating, gravure coating, die coating, slot coating, bar coating, wire rod coating, roller coating, or extrusion hopper coating. The composition can also be applied by spraying onto a suitable support (such as an on-press printing cylinder). Typically, the radiation-sensitive composition is applied and dried to form an imageable layer and a topcoat layer formulation can then be applied to that layer.

Illustrative of such manufacturing methods is mixing the radically polymerizable component, primary polymeric binder, initiator composition, radiation absorbing compound, and any other components of the radiation-sensitive composition in a suitable organic solvent or mixtures thereof [such as methyl ethyl ketone (2-butanone), methanol, ethanol, 1-methoxy-2-propanol, iso-propyl alcohol, acetone, γ-butyrolactone, n-propanol, tetrahydrofuran, and others readily known in the art, as well as mixtures thereof], applying the resulting solution to a substrate, and removing the solvent(s) by evaporation under suitable drying conditions. Some representative coating solvents and imageable layer formulations are described in the Examples below. After proper drying, the coating weight of the imageable layer is generally at least 0.1 and up to and including 5 g/m² or at least 0.5 and up to and including 3.5 g/m².

Layers can also be present under the imageable layer to enhance developability or to act as a thermal insulating layer. The underlying layer should be soluble or at least dispersible in the developer and typically have a relatively low thermal conductivity coefficient.

The imageable element may include what is conventionally known as an overcoat or topcoat layer (such as an oxygen impermeable topcoat) applied to and disposed over the imageable layer for example, as described in WO 99/06890 (Pappas et al.). Such topcoat layers comprise one or more water-soluble polymer binders chosen from such polymers as poly(vinyl alcohol)s, poly(vinyl pyrrolidone), poly(ethyleneimine), poly(vinyl imidazole), and copolymers of two or more of vinyl pyrrolidone, ethyleneimine, and vinyl imidazole, and generally have a dry coating weight of at least 0.1 and up to and including 2 g/m² (typically from about 0.1 to about 0.5 g/m²) in which the water-soluble polymer(s) comprise at least 50% and up to 98% of the dry weight of the topcoat layer. Topcoat layer polymer binders are also described in U.S. Pat. No. 3,458,311 (Alles), U.S. Pat. No. 4,072,527 (Fanni), and U.S. Pat. No. 4,072,528 (Bratt), and EP Publications 275,147A2 (Wade et al.), 403,096A2 (Ali), 354,475A2 (Zertani et al.), 465,034A2 (Ueda et al.), and 352,630A2 (Zertani et al.). The topcoat may have one or more poly(vinyl alchol)s as the predominant water-soluble polymer binders. These polymers can also be hydrolyzed to a degree of up to 98%.

The topcoat layer formulations can be prepared and applied in a similar fashion by dissolving or dispersing the desired components described above in suitable solvents or mixtures of solvents including but not limited to, water or water with one or more of iso-propanol, methanol, or other alcohols or ketones in an amount of up to 15 weight %. A surfactant may be included to improve coatability.

Intermediate drying steps may be used between applications of the various layer formulations to remove solvent(s) before coating other formulations. Drying steps at conventional times and temperatures may also help in preventing the mixing of the various layers.

Once the various layers have been applied and dried on the substrate, the imageable element can be enclosed in water-impermeable material that substantially inhibits the transfer of moisture to and from the imageable element as described in U.S. Pat. No. 7,175,969 (noted above) that is incorporated herein by reference.

The imageable elements can have any useful form including, but not limited to, flat plates, printing cylinders, printing sleeves (solid or hollow cores) and printing tapes (including flexible printing webs). Thus, the imageable elements can be of any size or shape (for example, square or rectangular) having the requisite one or more imageable layers disposed on a suitable substrate. Printing cylinders and sleeves are known as rotary printing members having a substrate and at least one imageable layer in cylindrical form. Hollow or solid metal cores can be used as substrates for printing sleeves.

### Imaging

During use, the imageable elements are exposed to a suitable source of imaging radiation at a wavelength of from about 300 to about 1500 nm and typically from about 750 to about 1250 nm. The lasers used for exposure are usually diode lasers, because of the reliability and low maintenance of diode laser systems, but other lasers such as gas or solid-state lasers may also be used. The combination of power, intensity and exposure time for laser imaging would be readily apparent to one skilled in the art.

The imaging apparatus can function solely as a platesetter or it can be incorporated directly into a lithographic printing press. In the latter case, printing may commence immediately after imaging, thereby reducing press set-up time considerably. The imaging apparatus can be configured as a flatbed recorder or as a drum recorder, with the printing plate mounted to the interior or exterior cylindrical surface of the drum. Examples of useful infrared imaging apparatus are available as models of Kodak® Trendsetter imagesetters available from Eastman Kodak Company (Burnaby, British Columbia, Canada) that contain laser diodes that emit near infrared radiation at a wavelength of about 830 nm. Other suitable imaging sources include the Crescent 42T Platesetter that operates at a wavelength of 1064 nm and the Screen PlateRite 4300 series or 8600 series platesetter (available from Screen, Chicago, Ill.). Additional useful sources of radiation include direct imaging presses that can be used to image a precursor while it is attached to the printing plate cylinder. An example of a suitable direct imaging printing press includes the Heidelberg SM74-DI press (available from Heidelberg, Dayton, Ohio).

Useful UV and “violet” imaging apparatus include Prosetter platesetters available from Heidelberger Druckmaschinen (Germany), Luxel Vx-9600 CTP and Luxel V-8 CTP platesetters available from Fuji Photo (Japan), Python platesetter (Highwater, UK), MakoNews, Mako 2, Mako 4, and Mako 8 platesetters available from ECRM (US), Micra platesetter available from Screen (Japan), Polaris and Advantage platesetters available from Agfa (Belgium), LaserJet platesetter available from Krause (Germany), and Andromeda® A750M platesetter available from Lithotech (Germany).

Infrared imaging speeds may be in the range of from about 50 to about 1500 mJ/cm², and typically from about 75 to about 400 mJ/cm². Image radiation in the UV or “violet” region of the spectrum can be carried out generally using energies of at least 0.01 mJ/cm² and up to and including 0.5 mJ/cm² and typically at least 0.02 and up to and including 0.1 mJ/cm².

While laser imaging is useful in the practice of this invention, imaging can be provided by any other means that provides thermal energy in an imagewise fashion. For example, imaging can be accomplished using a thermoresistive head (thermal printing head) in what is known as “thermal printing”, as described for example in U.S. Pat. No. 5,488,025 (Martin et al.) and as used in thermal fax machines and sublimation printers. Thermal print heads are commercially available (for example, as a Fujitsu Thermal Head FTP-040 MCS001 and TDK Thermal Head F415 HH7-1089).

Direct digital imaging is generally used for imaging. The image signals are stored as a bitmap data file on a computer. Raster image processor (RIP) or other suitable means may be used to generate such files. The bitmaps are constructed to define the hue of the color as well as screen frequencies and angles.

### Processing and Printing

Imaging of the imageable element can produce, for example, a lithographic printing plate that comprises a latent image of imaged (exposed) and non-imaged (non-exposed) regions.

In some embodiments, the imaged element can subjected to a post-exposure (pre-heat) step at a suitable temperature, for example from about 160 to about 220° C. for a time of up to two minutes. This would occur between imaging and processing.

With or without such post-exposure baking step, the imaged element is processed (developed) “off-press” using a solution that consists essentially of water (tap water, distilled water, etc.) as described below. Thus, there is no need for the processing solution to contain other components such as silicates, metasilicates, organic solvents, surfactants, chelating agents, and antifoaming agents. The processing solution pH is essentially neutral (that is between 6.5 and 7.5).

Processing the imaged element with water is carried out for a time sufficient to remove predominantly only the non-exposed regions of the imageable layer and underlying portions of any underlayers, and to reveal the hydrophilic surface of the substrate, but not long enough to remove significant amounts of the exposed regions. Thus, the imageable elements are “negative-working”. The revealed hydrophilic surface repels ink while the exposed (or imaged) regions accept ink. The non-imaged (non-exposed) regions of the imageable layer(s) are described as being “soluble” or “removable” in the processing solution because they are removed, dissolved, or dispersed within it more readily than the imaged (exposed) regions. Thus, the term “soluble” also means “dispersible”. If the imaged element has a topcoat layer, it can be removed between imaging and processing or it can be removed during processing with water.

Generally, water is applied to the imaged element by rubbing, spraying, jetting, dipping, immersing, coating, or wiping it with water or contacting the imaged element with a roller, impregnated pad, or applicator containing water. For example, the imaged element can be brushed with water, or water can be poured onto or applied by spraying the imaged surface with sufficient force to remove the unexposed regions using a spray nozzle system as described for example in [0124] of EP 1,788,431A2 (noted above). Still again, the imaged element can be immersed in water and rubbed by hand or with other mechanical means. The water is used in processing while it is at a temperature above room temperature and generally at a temperature of at least 30° C. or at a temperature of at least 40° C.

Water can also be applied in a processing unit (or station) as a component of a suitable apparatus that has at least one roller for rubbing or brushing the imaged element while water is applied. By using such a processing unit, the unexposed regions of the imaged layer may be removed from the substrate more completely and quickly. Residual water may be removed (for example, using a squeegee or nip rollers) or left on the resulting printing plate (and optionally dried) without any rinsing step. It is desirable that processing be carried out using processor systems and apparatus that allow the water to reside on the imaged element for sufficient time of interaction between the processing solution and the imaged coatings before mechanical means (such as brush or plush rollers) are used. Useful processing equipment includes a Quartz 850 RG that is currently available from NES Inc. (Westfield, Mass.) and a Heights Red Amber 40 that is currently available from Heights USA Inc. (Trenton, N.J.).

For example, processing can occur in a suitable apparatus in such a manner than the imaged element is transported at a speed of at least 1500 mm/min, or typically at least 2400 mm/min, to quickly and completely remove the non-imaged regions of the element, particularly when rollers or brushes are used as mechanical means.

Excess water can be collected in a tank and used several times, and replenished if necessary. It may also be desirable to apply a “fresh” sample of water to each imaged element.

In some embodiments, the resulting imaged element (for example lithographic printing plate) can be used for printing without any need for a separate rinsing step using water.

However, in other embodiments, the water-processed element is rinsed with additional water and treated with a gumming solution in a conventional manner before being used for printing.

The resulting lithographic printing plates can also be baked, after processing, in a postbake operation that can be carried out to increase run length. Baking can be carried out, for example, in a suitable oven at a temperature of less than 300° C. and typically at less than 250° C. for from about 2 to about 10 minutes. More typically, the baking is done very quickly at a temperature of from about 160° C. to about 220° C. (for example, at 190° C.) for up to five minutes (for example, up to two minutes). In some embodiments, the lithographic printing plates are postbaked at from about 160 to about 220° C. for up to two minutes Alternatively, the lithographic printing plates can be baked or cured by overall exposure to IR radiation at a wavelength of from about 800 to about 850 nm. This exposure creates conditions that enable very controllable baking effects with minimal distortion. For example, the lithographic printing plates can be passed through a commercial QuickBake 1250 oven (available from Eastman Kodak Company) at 4 feet (1.3 m) per minute at the 45% power setting of an infrared lamp to achieve a similar baking result from heating the plate in an oven at 200° C. for 2 minutes.

After processing (development), a lithographic ink and fountain solution can be applied to the printing surface of the lithographic printing plate for printing. The exposed regions of the imageable layer take up ink and the hydrophilic surface of the substrate revealed by the imaging and processing takes up the fountain solution. The ink is then transferred to a suitable receiving material (such as cloth, paper, metal, glass, or plastic) to provide one or more desired impressions of the image thereon. If desired, an intermediate “blanket” roller can be used to transfer the ink from the printing plate to the receiving material. The printing plates can be cleaned between impressions, if desired, using conventional cleaning means and chemicals.

The following examples are presented to illustrate the practice of this invention but are not intended to be limiting in any manner.

### EXAMPLES

The components and materials used in the examples and analytical methods used in evaluation were as follows. Unless otherwise indicated, the components can be obtained from Aldrich Chemical Company (Milwaukee, Wis.):

Polymer A: A polymer dispersion of Jeffamine-MA/AN/St/AA at 10/70/15/5 wt % (23.8% solid in n-propanol/water=76/24, acid number=33.4 mg KOH/g), was prepared by radical polymerization as described below.

Polymer B: A copolymer of AN/Methacrylamide/N-PMI/Acrylic acid at 48/20.4/13.6/18 wt % (acid number=111 mg KOH/g), was prepared by radical polymerization as described below.

BLO is γ-butyrolactone.

DMAC is N,N-dimethylacetamide.

Elvacite® 4026 is a hyperbranched poly(methyl methacrylate) obtained from Lucite International Inc. (Cordova, Tenn.).

FluorN™2900 is a fluorosurfactant obtained from Cytonix Corporation (Beltsville, Md.).

IB05 represents bis(4-t-butylphenyl) iodonium tetraphenylborate.

IPA represents iso-propyl alcohol.

Klucel M is hydroxypropylcellulose with Mw of about 850,000 g/mol obtained from Hercules Inc., Aqualon Division (Wilmington, Del.).

LL02 is a poly(vinyl alcohol) with a hydrolysis degree of 45% that was obtained from Nippon Gohse (Japan).

Masurf® FS-1520 is a fluoroaliphatic betaine fluorosurfactant, obtained from Mason Chemical Company (Arlington Heights, Ill.).

MEK represents methyl ethyl ketone.

NK Ester A-DPH is a dipentaerythritol hexaacrylate that was obtained from Kowa American (New York, N.Y.).

PGME is 1-methoxy-2-propanol.

Phosmer PE is an ethylene glycol methacrylate phosphate with 4-5 ethoxy groups, obtained from Uni-Chemical Co. Ltd.

Pigment 951 is a 27% solids dispersion of 7.7 parts of a polyvinyl acetal derived from poly(vinyl alcohol) acetalized with acetaldehyde, butyraldehyde, and 4-formylbenzoic acid, 76.9 parts of Irgalith Blue GLVO (Cu-phthalocyanine C.I. Pigment Blue 15:4), and 15.4 parts of Disperbyk® 167 dispersant (Byk Chemie) in 1-methoxy-2-propanol.

PVA 405 is a poly(vinyl alcohol) with a hydrolysis degree of 80% that was obtained from Kuraray (Japan).

PVA LM10HD is a poly(vinyl alcohol) with a hydrolysis degree of 38-42% that was obtained from Kuraray (Japan).

S0507 is an IR dye that was obtained from FEW Chemicals GmbH (Germany) having the following structure:

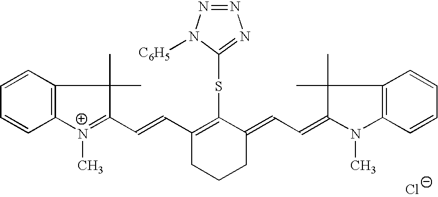

Sartomer SR415 is Ethoxylated (20) trimethylolpropane triacrylate from Sartomer Company, Inc. (Exton, Pa.).

Sartomer SR399 is dipentaerythritol pentaacrylate that was obtained from Sartomer Company, Inc.

Sartomer SR499 is Ethoxylated (6) trimethylolpropane triacrylate from Sartomer Company, Inc.

Varn Litho Etch 142W fountain solution was obtained from Varn International (Addison, Ill.).

Varn-120 plate cleaner was obtained from Varn International.

Varn PAR alcohol replacement was obtained from Varn International.

The “DH Test” used in the examples was a dry-heat accelerated aging test carried out at 48° C. for 5 days.

The “RH Test” was a high humidity accelerated aging test carried out at 38° C. and a relative humidity of 85% for 5 days.

### Synthesis of Polymer A

Preparation of Intermediate: Toluene (700 g) was charged into 2000-ml flask, followed by the addition of Jeffamine-2070 (225.4 g) [having predominantly PEG backbone, (MW-2000), available from Huntsman] in a N₂ atmosphere. Subsequently, methacryloyl chloride (11.85 g) and triethyl amine (12.75 g) were added over a period of 30 minutes, while maintaining temperature at 30° C. After the addition, the reaction mixture was kept for an additional 2 hrs at 30° C. The reaction mixture was cooled to room temperature and filtered, to remove the triethylamine hydrochloride salt and washed with 50 ml warm toluene. Toluene was subsequently removed under vacuum (100 mm) and heat (40° C.). The Intermediate was in liquid form.

### Synthesis of Polymer A:

10 g of intermediate step-I [Jeffamine-MA-2070], 84.8 g of DI water and 241.4 g of n-propanol were charged into a 1000 ml 4-neck flask, equipped with a heating mantle, temperature controller, mechanical stirrer, condenser, pressure equalized addition funnel and nitrogen inlet. The reaction mixture was heated slowly to slight reflux (78° C.). A pre-mixture of 15.0 g of styrene, 70 g of acrylonitrile, 5 g of acrylic acid and 0.7 g of azoisobutyronitrile (Vazo-64, from DuPont de Nemours Co) was added in two hours. Reaction was continued another fourteen hours and during processing, a total of (1.05 g) of Vazo 64 was added. During processing, the reaction temperature was raised to 80° C. After 19 hours, the conversion to graft copolymer was >94% based on determination of percent non-volatiles. The weight ratio of Jeffamine-MA-2070/styrene/acrylonitrile/acrylic acid was 10:15:70:5 in n-propanol/water (74:26 weight ratio). The acid number of Polymer A is 38.9 (theoretical)

### Synthesis of Polymer B:

100.6 g of Dimethylacetamide, 12 g of acrylonitrile, 5.1 g of methacrylamide, 3.4 g of N-phenyl maleimide, 4.5 g of acrylic acid, and 0.25 g of AIBN (Vazo-64, from DuPont de Nemours Co) were added in 500 ml 4-neck ground glass flask, equipped with a heating mantle, temperature controller, mechanical stirrer, condenser, pressure equalized addition funnel and nitrogen inlet. Then a pre-mixture of 135.0 g of dimethylacetamide, 36.0 g of acrylonitrile (AN), 15.3 g of methacrylamide, 10.2 g of N-phenyl maleimide, 13.5 g of acrylic acid and 0.5 g of AIBN was added in two hrs at 80° C. The reaction was continued another sixteen hours and during processing, a total of 1.25 g of AIBN was added. The polymer conversion was >99% based on determination of percentage of non-volatiles. The viscosity was (G.H′33) I (˜225 cps) at 30% non-volatile in DMAC. The weight ratio of AN/methacrylamide/phenyl maleimide/acrylic acid was 48/20.4/13.6/18 percent by weight. The product was isolated in powder form using ethanol/water mixture using lab dispersator (Model # 84, series 2000) at 4000 rpm. The cake was then re-slurried in ethanol. The material was dried in an oven overnight at 110° F. (43.3° C.). The resulting Polymer B had acid number 136.2.

### Invention Example 1

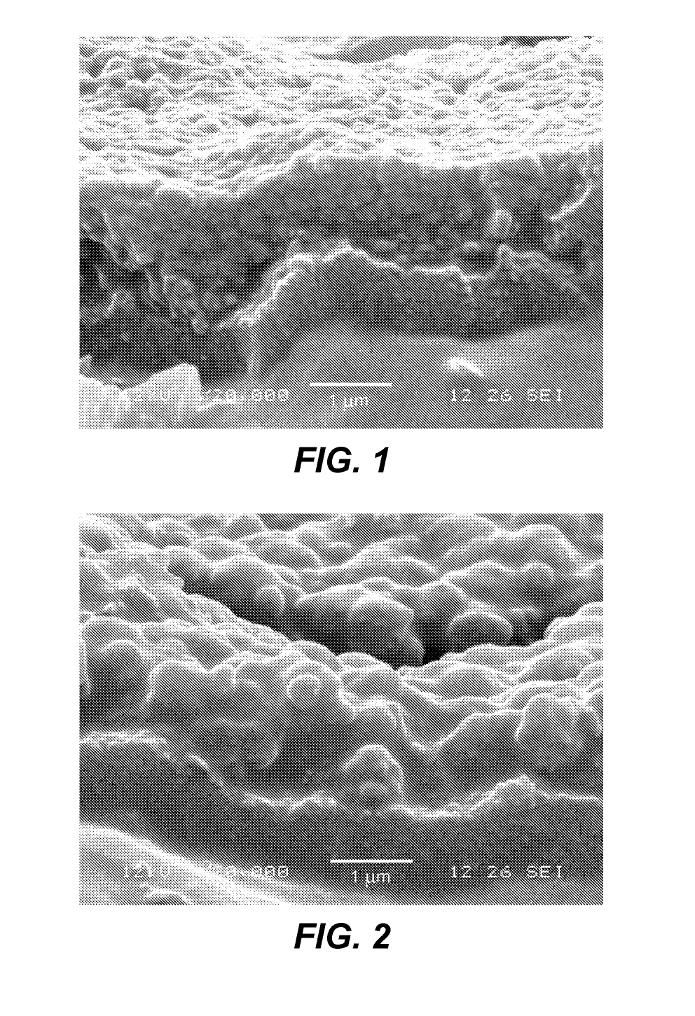

An imageable layer formulation was prepared by mixing 3.2 g of Polymer A dispersion, 0.4 g of SR499, 0.3 g of SR399, 0.3 g of NK ester A-DPH, 0.1 g of Phosmer PE, 0.15 g of IB-05, 0.05 g of S0507, 0.4 g of FluorN™ 2900 (5% in PGME), and 0.5 g of Pigment 951 in 1.5 g of BLO, 4.1 g of PGME, 6 g of MEK, 1 g of methanol, and 1 g of water. This formulation was applied to an electrochemically grained and sulfuric acid anodized aluminum substrate that had been post-treated with poly(vinyl phosphonic acid) to provide a dry coating weight of about 1.2 g/m². FIG. 1 shows a scanning electron microscope image of the resulting imageable layer. The imageable layer comprised discrete particles.

On the resulting imageable layer, a topcoat formulation comprising 4 g of PVA405, 4 g of IPA, 90 g of water, and 2 g of Masur® FS-1520 solution (1% in water) was applied to provide a dry coating weight of about 0.4 g/m². Both the imageable and topcoat formulations were applied using a wire-wound rod and sequentially dried for approximately 60 seconds in a Ranar conveyor oven set at 120° C.

The resulting imageable element was imaged with a power series from 10 to 100 mJ/cm² on a Kodak Trendsetter® 3244x image setter by exposing to an 830 nm IR laser, and was then developed manually with gentle scrubbing. This imaged element could be developed in less than 5 seconds in tap water at the temperature between 35 and 45° C. The minimum energy to achieve a solid image was about 20 to 30 mJ/cm².

With an exposure of 80 mJ/cm², a developed element was tested on an ABDick duplicator press charged with fountain solution containing Varn Litho Etch 142W at 3 oz./gal. (23.4 ml/liter) and PAR alcohol replacement at 3 oz./gal. (23.4 ml/liter) and van Son Rubber Base black ink VS151. Two hundred good impressions were printed without any signs of wear.

### Comparative Example 1

An imageable layer formulation was prepared by mixing 3.2 g of Polymer A dispersion, 0.4 g of SR499, 0.3 g of SR399, 0.3 g of NK ester A-DPH, 0.1 g of Phosmer PE, 0.15 g of IB-05, 0.05 g of S0507, 0.4 g of FluorN™ 2900 (5% in PGME), and 0.5 g of Pigment 951 in 13.6 g of DMAC. In the formulation, the Polymer A particles were distorted or even destroyed due to the addition of DMAC. This formulation was applied to an electrochemically grained and sulfuric acid anodized aluminum substrate that had been post-treated with poly(vinyl phosphonic acid) to provide a dry coating weight of about 1.2 g/m². FIG. 2 shows a scanning electron microscope image of the resultant imageable layer.

On the resulting imageable layer, a topcoat formulation comprising 4 g of PVA405, 4 g of IPA, 90 g of water, and 2 g of Masur® FS-1520 solution (1% in water) was applied to provide a dry coating weight of about 0.4 g/m². Both the imageable and topcoat formulations were applied using a wire-wound rod and sequentially dried for approximately 60 seconds in a Ranar conveyor oven set at 120° C.

The resulting imageable element was imaged with a power series from 10 to 100 mJ/cm² on a Kodak Trendsetter® 3244x imagesetter by exposing to an 830 nm IR laser, and was then developed manually with gentle scrubbing. This imaged element could not be developed in 1 minute using tap water at 45° C.

### Invention Example 2

An imageable layer formulation was prepared by mixing 1.4 g of Polymer A dispersion, 4.4 g of Polymer B solution (10% in BLO/PGME/MEK/H₂O=1.5/1/4.5/2), 0.4 g of SR499, 0.3 g of SR399, 0.3 g of NK ester A-DPH, 0.1 g of Phosmer PE, 0.15 g of IB-05, 0.05 g of S0507, 0.4 g of FluorN™ 2900 (5% in PGME), and 0.5 g of Pigment 951 in 1.5 g of BLO, 2.5 g of PGME, 5 g of MEK, 1 g of methanol, and 1 g of water. This formulation was applied to an electrochemically grained and sulfuric acid anodized aluminum substrate that had been post-treated with poly(vinyl phosphonic acid) to provide a dry coating weight of about 1.2 g/m².

On the resulting imageable layer, a topcoat formulation comprising 4 g of PVA405, 4 g of IPA, 90 g of water, and 2 g of Masur® FS-1520 solution (1% in water) was applied to provide a dry coating weight of about 0.4 g/m². Both the imageable and topcoat formulations were applied using a wire-wound rod and sequentially dried for approximately 60 seconds in a Ranar conveyor oven set at 120° C.

The resulting imageable element was imaged with a power series from 10 to 100 mJ/cm² on a Kodak Trendsetter® 3244x imagesetter by exposing to an 830 nm IR laser, and was then developed manually with gentle scrubbing. This imaged element could be developed in less than 5 seconds in tap water at the temperature between 25 and 45° C. The minimum energy to achieve a solid image was about 20 to 30 mJ/cm². This element could also be developed on a plate processing unit (Quartz 850 RG, NES Inc., Westfield, Mass.) charged with 45° C. tap water at the speed of 5.4 feet/min (1.64 m/min).

With an exposure of 80 mJ/cm², a developed element was tested on an ABDick duplicator press charged with fountain solution containing Varn Litho Etch 142W at 3 oz./gal. (23.4 ml/liter) and PAR alcohol replacement at 3 oz./gal. (23.4 ml/liter) and van Son Rubber Base black ink VS151. Two hundred good impressions were printed without any signs of wear.

### Invention Example 3

An imageable layer formulation was prepared by mixing 1.4 g of Polymer A dispersion, 4.4 g of Polymer B solution (10% in BLO/PGME/MEK/H2O=1.5/1/4.5/2), 0.4 g of SR415, 0.3 g of SR399, 0.3 g of NK ester A-DPH, 0.1 g of Phosmer PE, 0.15 g of IB-05, 0.05 g of S0507, 0.4 g of FluorN™ 2900 (5% in PGME), and 0.5 g of Pigment 951 in 1.5 g of BLO, 2.0 g of PGME, 6 g of MEK, 1 g of methanol, and 1 g of water. This formulation was applied to an electrochemically grained and sulfuric acid anodized aluminum substrate that had been post-treated with poly(vinyl phosphonic acid) to provide a dry coating weight of about 1.2 g/m².

On the resulting imageable layer, a topcoat formulation comprising 4 g of PVA405, 4 g of IPA, 90 g of water, and 2 g of Masur® FS-1520 solution (1% in water) was applied to provide a dry coating weight of about 0.4 g/m². Both the imageable and topcoat formulations were applied using a wire-wound rod and sequentially dried for approximately 60 seconds in a Ranar conveyor oven set at 120° C.

The resulting imageable element was imaged with a power series from 10 to 100 mJ/cm² on a Kodak Trendsetter® 3244x imagesetter by exposing to an 830 nm IR laser, and was then developed manually with gentle scrubbing. This imaged element could be developed in less than 5 seconds in tap water at the temperature between 40 and 45° C. The minimum energy to achieve a solid image was about 20 to 30 mJ/cm².

### Invention Example 4

An imageable layer formulation was prepared by mixing 2 g of Polymer A dispersion, 1.5 g of Polymer B solution (10% in BLO/PGME/MEK/H₂O=1.5/1/4.5/2), and 1.5 of LL02 solution (10% in PGME), 0.4 g of SR499, 0.3 g of SR399, 0.3 g of NK ester A-DPH, 0.1 g of Phosmer PE, 0.15 g of IB-05, 0.05 g of S0507, 0.4 g of FluorN™ 2900 (5% in PGME), and 0.5 g of Pigment 951 in 1.5 g of BLO, 2.0 g of PGME, 6 g of MEK, 1 g of methanol, and 1 g of water. This formulation was applied to an electrochemically grained and sulfuric acid anodized aluminum substrate that had been post-treated with poly(vinyl phosphonic acid) to provide a dry coating weight of about 1.2 g/m².

On the resulting imageable layer, a topcoat formulation comprising 4 g of PVA 405, 4 g of IPA, 90 g of water, and 2 g of Masur® FS-1520 solution (1% in water) was applied to provide a dry coating weight of about 0.4 g/m². Both the imageable and topcoat formulations were applied using a wire-wound rod and sequentially dried for approximately 60 seconds in a Ranar conveyor oven set at 120° C.

The resulting imageable element was imaged with a power series from 10 to 100 mJ/cm² on a Kodak Trendsetter® 3244x imagesetter by exposing to an 830 nm IR laser, and was then developed manually with gentle scrubbing. This imaged element could be developed in less than 10 seconds in tap water at 30° C. The minimum energy required to achieve a solid image was about 20 to 30 mJ/cm². After the 5-day “DH” and “RH” tests identified above, the imaged element was still developable in less than 20 seconds using tap water at 30° C.

With an exposure of 80 mJ/cm², a developed element was tested on an ABDick duplicator press charged with fountain solution containing Varn Litho Etch 142W at 3 oz./gal. (23.4 ml/liter) and PAR alcohol replacement at 3 oz./gal. (23.4 ml/liter) and van Son Rubber Base black ink VS151. Two hundred good impressions were printed without any signs of wear.

### Invention Example 5

An imageable layer formulation was prepared by mixing 2 g of Polymer A dispersion, 1.5 g of Polymer B solution (10% in BLO/PGME/MEK/H₂O=1.5/1/4.5/2), and 1.5 of PVA LM10HD solution (10% in PGME), 0.4 g of SR499, 0.3 g of SR399, 0.3 g of NK ester A-DPH, 0.1 g of Phosmer PE, 0.15 g of IB-05, 0.05 g of S0507, 0.4 g of FluorN™ 2900 (5% in PGME), and 0.5 g of Pigment 951 in 1.5 g of BLO, 2.0 g of PGME, 6 g of MEK, 1 g of methanol, and 1 g of water. This formulation was applied to an electrochemically grained and sulfuric acid anodized aluminum substrate that had been post-treated with poly(vinyl phosphonic acid) to provide a dry coating weight of about 1.2 g/m².

On the resulting imageable layer, a topcoat formulation comprising 4 g of PVA405, 4 g of IPA, 90 g of water, and 2 g of Masur® FS-1520 solution (1% in water) was applied to provide a dry coating weight of about 0.4 g/m². Both the imageable and topcoat formulations were applied using a wire-wound rod and sequentially dried for approximately 60 seconds in a Ranar conveyor oven set at 120° C.

The resulting imageable element was imaged with a power series from 10 to 100 mJ/cm² on a Kodak Trendsetter 3244x image setter by exposure to an 830 nm IR laser, and was then developed manually with gentle scrubbing. This imaged element could be developed in less than 20 seconds in tap water at 40° C. The minimum energy to achieve a solid image was about 20 to 30 mJ/cm².

### Invention Example 6

An imageable layer formulation was prepared by mixing 2.7 g of Polymer A dispersion, 1.0 g of Elvacite® 4062 solution (10% in MEK), and 2.0 of Klucel M solution (2% in water), 0.4 g of SR499, 0.3 g of SR399, 0.3 g of NK ester A-DPH, 0.1 g of PhosmerPE, 0.15 g of IB-05, 0.05 g of S0507, 0.4 g of FluorN™ 2900 (5% in PGME), and 0.5 g of Pigment 951 in 1.5 g of BLO, 2.0 g of PGME, 6 g of MEK, 1 g of methanol, and 1 g of water. This formulation was applied to an electrochemically grained and sulfuric acid anodized aluminum substrate that had been post-treated with poly(vinyl phosphonic acid) to provide a dry coating weight of about 1.1 g/m².

On the resulting imageable layer, a topcoat formulation comprising 4 g of PVA405, 4 g of IPA, 90 g of water, and 2 g of Masur® FS-1520 solution (1% in water) was applied to provide a dry coating weight of about 0.4 g/m². Both the imageable and topcoat formulations were applied using a wire-wound rod and sequentially dried for approximately 60 seconds in a Ranar conveyor oven set at 120° C.

The resulting imageable element was imaged with a power series from 10 to 100 mJ/cm² on a Kodak Trendsetter® 3244x imagesetter by exposing to an 830 nm IR laser, and was then developed manually with gentle scrubbing. This imaged element could be developed in less than 10 seconds in tap water at 45° C. The minimum energy required to achieve a solid image was about 20 to 30 mJ/cm².

### Comparative Example 2

An imageable layer formulation was prepared by mixing 7.7 g of Polymer B solution (10% in BLO/PGME /MEK/H₂O=1.5/1/4.5/2), 0.4 g of SR499, 0.3 g of SR399, 0.3 g of NK ester A-DPH, 0.1 g of Phosmer PE, 0.15 g of IB-05, 0.05 g of S0507, 0.4 g of FluorN™ 2900 (5% in PGME), and 0.5 g of Pigment 951 in 1.5 g of BLO, 2.5 g of PGME, 4.1 g of MEK, and 1 g of methanol. This formulation was applied to an electrochemically grained and sulfuric acid anodized aluminum substrate that had been post-treated with poly(vinyl phosphonic acid) to provide a dry coating weight of about 1.2 g/m².

On the resulting imageable layer, a topcoat formulation comprising 4 g of PVA405, 4 g of IPA, 90 g of water, and 2 g of Masur® FS-1520 solution (1% in water) was applied to provide a dry coating weight of about 0.4 g/m². Both the imageable and topcoat formulations were applied using a wire-wound rod and sequentially dried for approximately 60 seconds in a Ranar conveyor oven set at 120° C.

The resulting imageable element was imaged with a power series from 10 to 100 mJ/cm² on a Kodak Trendsetter® 3244x imagesetter by exposure to an 830 nm IR laser, and was then developed manually with gentle scrubbing. This imaged element could not be developed within 1 minute using tap water at 45° C.

### Comparative Example 3

An imageable layer formulation was prepared by mixing 1.4 g of Polymer A dispersion, 4.4 g of Polymer B solution (10% in BLO/PGME/MEK/H₂O=1.5/1/4.5/2), 0.4 g of SR499, 0.3 g of SR399, 0.3 g of NK ester A-DPH, 0.1 g of Phosmer PE, 0.15 g of IB-05, 0.05 g of S0507, 0.4 g of FluorN™ 2900 (5% in PGME), and 0.5 g of Pigment 951 in 11 g of DMAC. In the formulation, the Polymer A particles were distorted or even destroyed due to the addition of DMAC. This formulation was applied to an electrochemically grained and sulfuric acid anodized aluminum substrate that had been post-treated with poly(vinyl phosphonic acid) to provide a dry coating weight of about 1.2 g/m².

On the resulting imageable layer, a topcoat formulation comprising 4 g of PVA405, 4 g of IPA, 90 g of water, and 2 g of Masur® FS-1520 solution (1% in water) was applied to provide a dry coating weight of about 0.4 g/m². Both the imageable and topcoat formulations were applied using a wire-wound rod and sequentially dried for approximately 60 seconds in a Ranar conveyor oven set at 120° C.

The resulting imageable element was imaged with a power series from 10 to 100 mJ/cm² on a Kodak Trendsetter® 3244x imagesetter by exposing to an 830 nm IR laser, and was then developed manually with gentle scrubbing. This imaged element could not be developed within 1 minute using tap water at 45° C.

The invention has been described in detail with particular reference to certain preferred embodiments thereof, but it will be understood that variations and modifications can be effected within the spirit and scope of the invention.

1. A negative-working imageable element comprising a substrate and having thereon an imageable layer comprising:
a free-radically polymerizable component,
an initiator composition that is capable of generating free radicals sufficient to initiate polymerization of said free-radically polymerizable component upon exposure to imaging radiation in the presence of a radiation absorbing compound,
a radiation absorbing compound, and
a polymeric binder that is present as discrete particles and comprises polyetheramine side chains connected to a backbone.

2. The element of claim 1 wherein said polyetheramine side chains comprise at least 5 alkylene oxide segments.

3. The element of claim 1 wherein said polyetheramine side chains comprise from 5 to 90 alkylene oxide segments.

4. The element of claim 1 wherein each of said polyetheramine side chains have a molecular weight of at least 600.

5. The element of claim 1 wherein said polymeric binder comprises recurring units represented by the following Structure (PB): 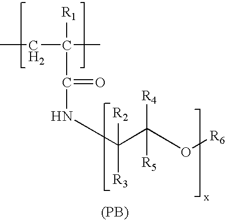
wherein x is from 5 to 90 and R₁ to R₆ are independently hydrogen or an alkyl group that may be the same or different in each recurring unit.

6. The element of claim 5 wherein said recurring units (PB) comprise at least 2 mol % of all recurring units in said polymeric binder.

7. The element of claim 1 wherein said polymeric binder is represented by the following Structure (IA):
-(A)ᵣ-(B)ₛ—(C)ₜ-(D)_{w}- (IA)
wherein A represents recurring units having said polyetheramine side chains comprising from 5 to 90 alkylene oxide segments, B represents recurring units comprising pendant cyano groups, C represents recurring units having pendant acidic groups, and D represents recurring units other than those represented by A, B, and C, r is from about 1 to about 30 mol %, s is from about 10 to about 80 mol %, t is from about 1 to about 30 mol %, and w is from 0 to about 50 mol %.

8. The element of claim 1 wherein said polymeric binder is present as discrete particles having an average diameter of from about 30 to about 2000 nm.

9. The element of claim 1 wherein said initiator composition comprises a diaryliodonium borate comprising a diaryliodonium cation that is represented by the following Structure (IB): 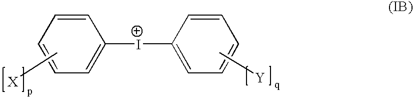
wherein X and Y are independently halo, alkyl, alkyloxy, aryl, or cycloalkyl groups, or two or more adjacent X or Y groups can be combined to form a fused carbocyclic or heterocyclic ring with the respective phenyl groups, p and q are independently 0 or integers of 1 to 5, provided that either p or q is at least 1, and
a boron-containing anion that is represented by the following Structure (IB_{Z}): 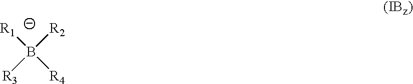
wherein R₁, R₂, R₃, and R₄ are independently alkyl, carbocyclic aryl, alkenyl, alkynyl, cycloalkyl, or heterocyclyl groups, or two or more of R₁, R₂, R₃, and R₄ can be joined together to form a heterocyclic ring with the boron atom.

10. The element of claim 1 wherein said polymeric binder is present in an amount of from about 10 to about 70% based on imageable layer dry weight.

11. The element of claim 1 wherein said radiation absorbing compound has a λₘₐₓ of from about 700 to about 1400 nm.

12. The element of claim 1 that is a negative-working lithographic printing plate precursor having an aluminum-containing substrate.

13. The element of claim 1 further comprising a topcoat layer disposed on said imageable layer.

14. The element of claim 13 wherein said topcoat layer comprises predominantly a poly(vinyl alcohol).

15. A method of making an image comprising:
A) imagewise exposing the negative-working imageable element of claim 1 to imaging radiation to provide both exposed and non-exposed regions in the imageable layer, and
B) applying water to said imaged element to remove predominantly only said non-exposed regions.

16. The method of claim 15 wherein said imaging radiation is at from about 700 to about 1400 nm.

17. The method of claim 15 wherein water applied in step B is at a temperature of at least 30° C.

18. The method of claim 15 wherein water is applied in step B in combination with using mechanical rubbing means to remove said non-exposed regions of said imageable layer.

19. The method of claim 15 wherein step B is carried out in a processing apparatus wherein said imaged element is transported at a speed of at least 1500 mm/min.

20. The method of claim 15 further comprising baking said imaged element after step B at from about 160 to about 220° C. for up to two minutes.

21. The method of claim 15 wherein said element comprises a polymeric binder that is present as discrete particles having an average diameter of from about 60 to about 500 nm and comprises polyetheramine side chains connected to a backbone, wherein said polyetheramine side chains comprise from 5 to 90 alkylene oxide segments.

22. A lithographic printing plate obtained by the method of claim 15.
